(19) United States
(12) Patent Application Publication
(10) Pub. No.: US 2026/0060145 A1
(43) Pub. Date: Feb. 26, 2026

(54) VERTICAL INTEGRATED VOLTAGE REGULATOR

(71) Applicant: Arm Limited, Cambridge (GB)

(72) Inventors: Yimajian Yan, Santa Clara, CA (US); Rainer Herberholz, Great Abington (GB); Peter Andrew Rees Williams, Great Abington (GB); Stuart James Aitken, Cambridge (GB); Sumant Srikant, Cambridge (GB); George John Scott, Chandler, AZ (US); Javier DeLaCruz, San Jose, CA (US)

(21) Appl. No.: 19/292,769

(22) Filed: Aug. 6, 2025

Related U.S. Application Data
(60) Provisional application No. 63/685,541, filed on Aug. 21, 2024.

(51) Int. Cl. H01L 25/18; H01L 25/00; H05K 1/18

(52) U.S. Cl. CPC H01L 25/18; H01L 25/50; H05K 1/181; H05K 2201/10378

(57) ABSTRACT

An integrated circuit assembly comprises an integrated circuit die and a substrate electrically and physically coupled to the integrated circuit die on a first mounting surface of the substrate. A vertically integrated voltage regulator assembly comprises one or more inductors and one or more voltage regulation circuits, and is electrically and physically connected to the substrate at a physical location on a second mounting surface of the substrate opposite the first mounting surface of the substrate. At least a portion of the vertically integrated voltage regulator assembly and at least a portion of the integrated circuit die are intersected by an axis normal to and through first and second mounting surfaces. An array of electrical connections are coupled to the substrate and electrically connected to the integrated circuit die, the array of electrical connections operable to electrically connect the substrate to a printed circuit board and/or to a socket.

This application claims the benefit of priority under 35 USC § 119(c) to U.S. Provisional Ser. No. 63/685,541 filed on Aug. 21, 2024 and titled VERTICAL INTEGRATED VOLTAGE REGULATOR, which is hereby incorporated herein by reference in its entirety.

### FIELD

The field relates to powering integrated circuit devices, and more specifically to a vertical integrated voltage regulator for integrated circuits.

### BACKGROUND

Modern computerized devices process and store information in a variety of ways, including using processors that may have multiple cores and cache memory that may be associated with each of at least some of the processor cores. The processors in modern high-performance consumer electronics devices such as smart phones, tablet computers, set top boxes, and the like, may have different processor cores with different capabilities, such as high-performance processor cores that can perform a high number of operations per second but that may consume a significant amount of power, and efficient cores that may perform tasks more efficiently but at a lower peak number of instructions per second than high performance cores. In some further examples, at least some of the high-performance cores and/or efficient cores may have configurable performance levels, such as underdriven or overdriven voltage levels and corresponding faster or reduced operating speeds.

Processor cores in some examples may be powered up or down as needed, and in further examples may have one or more different available performance levels (and associated efficiency levels) per core. For example, a demanding video game involving rendering many objects in real time may use both high-performance cores and all the high-efficiency cores in a smartphone, while a simple task like reading email may use a single high-efficiency core. Cores may therefore be selectively powered up or selectively employed to process program instructions depending on the task load in a computing device, typically involving significant changes in power demand as different processor cores are made active or employed to process instructions.

A large integrated circuit die may also have variances in semiconductor behavior across the die or between dies (sometimes known as process corner variances), and voltages needed for different clock frequencies or performance levels of different cores may also vary significantly. Individual control of voltages for each processor core or group of processor cores is therefore desirable in some multi-core computing systems to minimize power consumption by providing each core with no more than the voltage required for reliable operation at a given performance level or clock frequency. High granularity of voltage level provided to different processor cores in a computing system via voltage regulation external to the integrated circuit die may simplify power delivery to the die, but may present challenges related to the physical wire distance and impedance between the voltage regulator and the integrated circuit die.

Multi-core processors in modern computing systems may also have their own cache memory, such as a dedicated level one (L1) or level two (L2) cache memory associated with some or all of the respective processor cores in the multi-core processor. L1 or L2 cache local to one or more processor cores may store frequently-used data local to the respective cores, which may make retrieval of this often-used data faster than if the same data was retrieved from Level 3 (L3) cache or main memory (or DRAM) that is typically slower and physically more remote. Cache memory may typically contain tens of thousands or hundreds of thousands (or more) of words of data per core, comprising a significant percentage of the die area, transistor count, and power consumed by the integrated device, and may be powered up and down or switched between active and inactive power states as processor cores are powered up and down.

When processor cores are powered on to provide greater computing resources for a computing system, they may quickly draw significantly more current than before the cores and cache were powered, potentially causing a droop in voltage provided to the processor circuits. High-performance application such as servers configured to process artificial intelligence workloads may further contain thousands of cores, including hundreds of cores per integrated circuit, drawing power exceeding a kilowatt. Providing power to such cores through a voltage regulator on a motherboard may present some difficulty due to the physical distance and impedance between the voltage regulator circuitry and the integrated circuit die. Voltage regulators are often therefore designed to provide high current capability to an integrated circuit die while limiting effects such as voltage droop. But, voltage regulator circuitry may be slow to respond due to factors such as physical distance and impedance between the voltage regulator and integrated circuit. For reasons such as these, a need exists for improved voltage supply and regulation in powering integrated circuits such as processor cores and associated cache memory.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 is a side view of an integrated circuit package comprising a vertically integrated voltage regulator and a socket with a cavity, consistent with an example embodiment.

FIG. 2 is a side view of an integrated circuit package comprising a vertically integrated voltage regulator mounted in a socket with a cavity, consistent with an example embodiment.

FIG. 3 is a side view of an integrated circuit package comprising a vertically integrated voltage regulator and a printed circuit board with a cavity, consistent with an example embodiment.

FIG. 4 is a side view of an integrated circuit package comprising a vertically integrated voltage regulator mounted on a printed circuit board with a cavity, consistent with an example embodiment.

FIG. 5 is a side view of an integrated circuit package having tiled vertically integrated voltage regulators, consistent with an example embodiment.

FIG. 6 is a flow diagram of a method of assembling an integrated circuit package with a vertically integrated voltage regulator assembly, consistent with an example embodiment.

FIG. 7 shows a block diagram of a general-purpose computerized system, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Many modern computing systems employ processors with multiple processing cores, such that certain tasks that can be performed in parallel can be distributed among the cores for faster execution or different tasks can be performed simultaneously by different processors. Simple tasks such as checking an email may only use one processor core, while more complex tasks such as rendering a video game in real time may use all available cores. The processor cores in further examples may be associated with cache memory local to one or more of the respective processor cores, operable to store information that the processor core is likely to need for executing program instructions using local SRAM for fast access.

In some examples the different processor cores may also include different types of circuits, such as high performance processor cores, high efficiency processor cores, memory, and other such circuits. These circuits may vary in power demand, in physical location on the die, and on power demand per unit of area on the die. Powering processor cores and their related caches up and down changes the current drawn from the power source for the processor cores (and, in some further examples, associated cache memory), and may cause a temporary droop in supplied voltage while the voltage regulator or other power supply components recover from the increased demand for power. This voltage droop may be controlled to some degree using methods such as a low-dropout voltage regulator that responds somewhat quickly to changes in drawn current, by using bypass capacitors to store extra charge that is available to help meet a sudden demand for additional current, or through other such means. But, the impedance of low-dropout voltage regulator and the distance between the voltage regulator and the integrated circuit die may limit its ability to respond quickly to changes in power demand. Problems such as these may be exacerbated by high-performance or high-density integrated circuit devices, such as integrated circuits holding hundreds of processor cores for machine learning processing that may consume hundreds or thousands of watts of power.

Some examples presented herein therefore provide for an improved voltage regulator for integrated circuit dies and packages, comprising a voltage regulator assembly that may overlap or be in the same axis normal to the plane of the integrated circuit die and the voltage regulator assembly circuit board. The voltage regulator assembly may be attached to a substrate to which the integrated circuit die is attached, such as a package substrate, on an opposite mounting surface or opposite side of the substrate as the integrated circuit die, thereby positioning the voltage regulator assembly physically near the integrated circuit die. One or more cavities or openings may be formed in a mounting surface of a circuit board, such as a cavity in a mounting socket, a cavity in the circuit board, or a combination thereof to accommodate the voltage regulator assembly such that the voltage regulator assembly is physically located at least partially within the cavity.

In a more detailed example, an integrated circuit assembly comprises an integrated circuit die, and a substrate electrically and physically coupled to the integrated circuit die on a first mounting surface of the substrate. A vertically integrated voltage regulator assembly comprises one or more inductors and one or more voltage regulation circuits, the vertically integrated voltage regulator assembly electrically and physically connected to the substrate at a physical location on a second mounting surface of the substrate opposite the first mounting surface of the substrate. At least a portion of the vertically integrated voltage regulator assembly and at least a portion of the integrated circuit die are intersected by an axis normal to and through first and second mounting surfaces. An array of electrical connections are coupled to the substrate and electrically connected to the integrated circuit die, the array of electrical connections operable to electrically connect the substrate to a printed circuit board and/or to a socket.

In another example, a method of forming an integrated circuit assembly comprises physically and electrically coupling an integrated circuit die to a first mounting surface of a substrate, and physically and electrically coupling a vertically integrated voltage regulator assembly to the substrate at a physical location on a second mounting surface of the substrate opposite the first mounting surface of the substrate. At least a portion of the vertically integrated voltage regulator assembly and at least a portion of the integrated circuit die are intersected by an axis normal to and through the first and second mounting surfaces, the vertically integrated voltage regulator assembly comprising one or more inductors and one or more voltage regulation circuits. An array of electrical connections are formed coupled to the substrate and electrically connected to the integrated circuit die, the array of electrical connections further operable to electrically connect the substrate to a printed circuit board and/or to a socket.

In an alternate example, an integrated circuit assembly comprises an integrated circuit die, and a substrate electrically and physically coupled to the integrated circuit die on a first mounting surface of the substrate. A printed circuit board is electrically and physically coupled to the substrate at a physical location on a second mounting surface of the substrate opposite the first mounting surface of the substrate, and on a first mounting surface of the printed circuit board. A vertically integrated voltage regulator assembly comprises one or more inductors and one or more voltage regulation circuits, and is electrically and physically connected to the printed circuit board at a physical location on a second mounting surface of the printed circuit board opposite the first mounting surface of the printed circuit board, wherein at least a portion of the vertically integrated voltage regulator assembly and at least a portion of the integrated circuit die are intersected by an axis normal to and through the first and second mounting surfaces of the printed circuit board.

Examples such as these illustrate how a voltage regulator assembly can be mounted physically near an integrated circuit die, shortening the length and reducing the impedance of electrical connections between the voltage regulator and the integrated circuit die. Such an assembly may allow the voltage regulator to more quickly respond to changes in observed voltage on the integrated circuit die, such as during transients or rapid changes in drawn current, and may provide for more efficient delivery of power to the integrated circuit die with less loss, delay, and other impedance-related or distance-related artifacts.

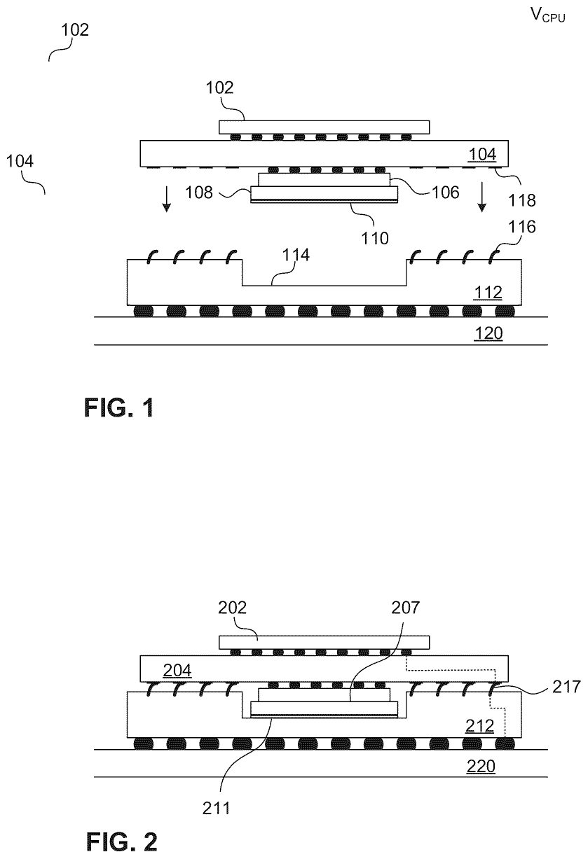

FIG. 1 is a side view of an integrated circuit package comprising a vertically integrated voltage regulator and a socket with a cavity, consistent with an example embodiment. Here, an integrated circuit die 102 is electrically and physically coupled to a substrate 104. The integrated circuit may in various embodiments comprise various digital analog, or mixed circuits. Digital circuit examples include one or more processor cores, graphics processors, memory, signal processors, and other digital circuits, while analog circuit examples include amplifiers, filters, analog communication circuits, and the like. Mixed signal integrated circuits may contain both digital and analog circuits on the same device, such as a wireless networking integrated circuit operable to process both analog radio waves and digital data signals to facilitate transmission and/or reception of digital data using analog radio waves. The substrate 104 in various examples may comprise a fiberglass and resin, organic laminate, ceramic, or other suitable material, and may contain within it one or more conductive layers comprising various signal, power, and other electrical interconnects coupling the flip-chip bumps to ball grid array (BGA) solder balls, Land Grid Array (LGA) contact pads, Pin Grid Array pins, metal pillars, bumps, or other package electrical connections.

The substrate 104 in this example is further connected to vertically integrated voltage regulator via an array of bumps, such as flip chip bumps, where the vertically integrated voltage regulator comprises one or more inductors 106, a voltage regulation circuit 108, and a thermal interface 110. The voltage regulation circuit 108 in various embodiments may be operable to monitor one or more voltage signals on the integrated circuit die 102, and/or monitor one or more voltage signals provided from the vertically integrated voltage regulator assembly to the processor die. The voltage regulator in various examples may be a Low-Dropout Voltage Regulator (LDO voltage regulator) operable to regulate output voltages that are very close to the supply voltage, a linear voltage regulator, or other type of suitable voltage regulator. The voltage regulator may in further examples comprise a DC to DC voltage converter, such as a buck converter or other suitable voltage converter circuit. The voltage regulator circuit in various examples may include one more power components such as one or more inductors (and/or capacitors), which may be physically large relative to other voltage regulator assembly components and so are shown at 106 as being external to the voltage regulation circuit 108.

The vertically integrated voltage regulator assembly further comprises a thermal interface 110, which is configured to thermally and physically couple to a thermally conductive material such as a heat sink to draw unwanted thermal energy away from the vertically integrated voltage regulator and cool the assembly. The heat sink may in various example embodiments comprise a metal or other thermally conductive material, such as a block of metal having a high thermal mass, a block of metal comprising an array of pins or fins configured to increase surface area to dissipate heat into the surrounding air, or the like. In further examples, air, liquid, or other material may be circulated in contact with the heat sink to carry heat away from the heat sink, such as via a fan or a pump. The vertically integrated voltage regulator may further be coupled to a heat sink via a thermal interface 110, such as thermal paste, thermal tape, or other material designed to fill any gaps and ensure good thermal conductivity between the vertically integrated voltage regulator and a heat sink.

The assembly shown at 102-110 comprises in the example of FIG. 1 a die, a substrate, and a vertically integrated voltage regulator, such that the assembly may be coupled to a printed circuit board or otherwise coupled to a circuit such as a computerized system via a socket 112. The assembly shown at 102-110 may in other embodiments comprise additional components, such as underfill material filling gaps between solder balls in the flip chip ball gird arrays, a protective package covering the top of the die 102 and providing thermal conductivity to a heat sink for the integrated circuit die, and other such components. The socket in the example of FIG. 1 comprises a cavity 114 formed in a surface of the socket facing the vertically integrated voltage regulator, such that when the assembly shown at 102-110 is inserted in the socket, the thermal interface 110 makes contact with a bottom portion of the cavity 114. In other examples, the voltage regulator may be sufficiently thin that no cavity is needed. The socket further comprises an array of semi-flexible pins 116, comprising part of a Land Grid Array (LGA) chip/socket interface, where the pins 116 are operable to make physical and electrical contact with a corresponding array of conductive pads 118 on the substrate 104.

The socket 112 in this example is coupled to the printed circuit board 120 via solder balls that are larger than the flip chip ball grid array solder balls coupling the integrated circuit die 102 to the substrate 104, and coupling the substrate 104 to the vertically integrated voltage regulator comprising inductors 106 and voltage regulator circuit 108. These solder balls may be a ball grid array, and may be underfilled such as with an epoxy resin or other material that flows via capillary action to fill air space between the socket 112 and the printed circuit board 120 to prevent thermal stress from heating and cooling air pockets between the socket and the printed circuit board. The socket 112 in other examples may be another type of socket, such as a pin socket, a Pin Grid Array (PGA) socket, bumps such as solder bumps or metal pillars coated in solder, or another suitable connection designed or configured to physically and electrically connect to the substrate 104. Circuit traces on the printed circuit board 120 are thereby electrically connected to the integrated circuit die 102 via the socket and the substrate, and the various physical and electrical connection mechanisms that may be employed to couple these components to one another.

The die 102, substrate 104, and vertically integrated voltage regulator comprising inductors 106 and voltage regulator circuit 108 are configured in the example of FIG. 1 such that the vertically integrated voltage regulator is physically near the integrated circuit die, and electrical connections between the two via substrate 104 are relatively short and have a relatively low impedance. This enables relatively rapid response to detected changes in voltage in the integrated circuit die 102, and relatively low losses due to impedance or physical distance between the vertically integrated voltage regulator and the integrated circuit die. The configuration of FIG. 1 may therefore be able to respond to changes in power demand, such as may cause voltage transients, better than other known configurations, and may experience less loss or delay in responding to changes in power demand due to the physical proximity and reduced impedance between the vertically integrated voltage regulator and the integrated circuit die. In a more detailed example, distances between power output electrical connections of the voltage regulator circuit 108 limited such that low inductance and resistance between the voltage regulator and integrated circuit circuitry provide efficient power delivery and rapid response to changes in power demand. The voltage regulator 108 in the example of FIG. 1 may receive incoming power at a higher voltage than one or more output power signals, and incoming power bumps, pins, and/or the like need not be in close proximity to the integrated circuit but may be routed through substrate 104 or through other such means.

FIG. 2 is a side view of an integrated circuit package comprising a vertically integrated voltage regulator mounted in a socket with a cavity, consistent with an example embodiment. Here, the integrated circuit assembly comprising integrated circuit die 202, substrate 204, and vertically integrated voltage regulator 207 (as shown in the top portion of FIG. 1) are lowered into position on socket 212, which couples the integrated circuit assembly both electrically and physically to the printed circuit board 220. Thermal interface 211, such as thermal paste or the like, ensures a good thermal connection between the vertically integrated voltage regulator 207 and the metal socket 212, transferring heat to the socket. In a further example, the socket may comprise or be coupled to a heat sink to help further dissipate heat from the vertically integrated voltage regulator into the surrounding air or another cooling gas or fluid.

Land Grid Array (LGA) pins on the socket physically contact conductive pads on the substrate 204 as shown at 217, providing electrical signal connections between the circuitry on the printed circuit board 220 and the integrated circuit die 202, while other examples may employ pin grid array (PGA) or other such electrical connections. Dashed lines represent electrical connections, such as metal wire or circuit board traces, linking the socket 212's ball grid array balls coupling the socket to the printed circuit board and the land grid array pins coupling the socket to the integrated circuit assembly. Dashed lines similarly represent a connection between the substrate contact pads that interface with the socket's land grid array pins and electrically couple them to the integrated circuit die 202 via flip chip ball grid array solder balls, completing an electrical connection between the printed circuit board 220 and the mounted integrated circuit assembly's integrated circuit die 202. Some such connections may provide one or more power supply signals, and may in various examples be routed via flip chip ball grid array solder balls or another suitable electrical connection (such as metal pillars that are coated in solder) to the vertically integrated voltage regulator 207, enabling the vertically integrated voltage regulator 207 to regulate the voltage of power signals used to power various circuits within the integrated circuit die 202.

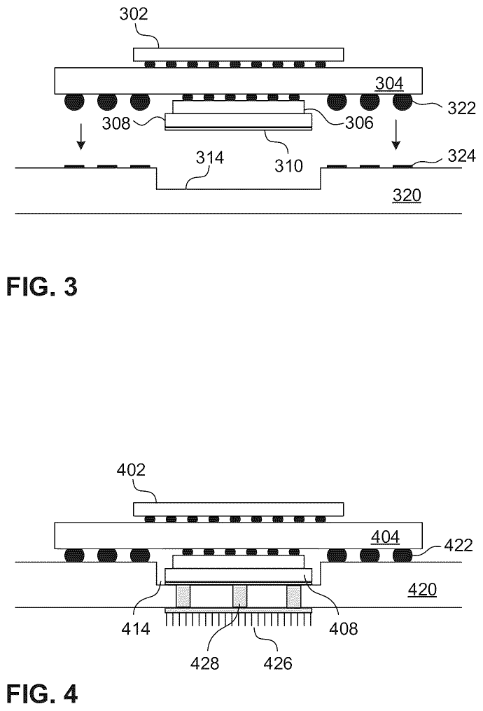

FIG. 3 is a side view of an integrated circuit package comprising a vertically integrated voltage regulator and a printed circuit board with a cavity, consistent with an example embodiment. Here, an integrated circuit die 302 is attached to a substrate 304 such as using a flip chip ball grid array and underfill, similar to the example of FIG. 1. A vertically integrated voltage regulator comprising one or more inductors 306, voltage regulation circuitry 308, and a thermal interface 310 are also similarly mounted to the substrate 304. A printed circuit board 320 has a cavity 314 formed therein, configured to at least partially receive the vertically integrated voltage regulator assembly and in a further example to provide a thermal sink for heat conducted from the vertically integrated voltage regulator assembly via thermal interface 310.

The integrated circuit assembly comprising the integrated circuit die 302, substrate 304, and vertically integrated voltage regulator assembly 306-310 are configured in the example of FIG. 3 to be coupled to a printed circuit board 320 via a ball grid array, comprising an array of solder bumps on the substrate 322 and an array of conductive pads 324 on the printed circuit board configured to receive and be electrically and physically coupled to the ball grid array's solder bumps 322. In a more detailed example, the solder bumps 322 of the ball grid array are formed on pads on the substrate 304, and are heated upon mating the integrated circuit assembly to the printed circuit board 320, causing the solder bumps to melt and link pads on substrate 304 with a corresponding array of pads on the printed circuit board 324.

In other examples, other bumps, metal pillars, and/or the like, such as solder-coated copper pillars, may be employed in place of solder bumps 322 and/or other solder bumps shown in these examples. In an another embodiment, the cavity 314 may be omitted, such as where solder-coated metal pillars used in place of bumps 322, to provide sufficient room for a voltage regulator assembly to be mounted between the printed circuit board 32 and the substrate 304.

FIG. 4 is a side view of an integrated circuit package comprising a vertically integrated voltage regulator mounted on a printed circuit board with a cavity, consistent with an example embodiment. Here, the integrated circuit assembly of FIG. 3, comprising the integrated circuit die 402, substrate 404, and vertically integrated voltage regulator 408, are mounted to the printed circuit board 420 via solder bumps 422. The solder bumps 422 may be a ball grid array, and may in various embodiments comprise solder balls formed on conductive pads such as are shown at 324 of FIG. 3 on either the substrate 404 and/or the printed circuit board 420. In one embodiment, the integrated circuit assembly is aligned so that its ball grid array bumps align with the ball grid array pads on the printed circuit board 42, and the vertically integrated voltage regulator is aligned to be located at least partially within the cavity 414 formed in the printed circuit board. The integrated circuit assembly and printed circuit board are then heated, causing the solder balls or bumps forming a part of the ball grid array melt and flow, physically and electrically connecting the substrate 404 to the printed circuit board 420. In a further example, empty space between the solder balls 422 of the ball grid array may be underfilled, such as with epoxy or another suitable material.

The vertically integrated voltage regulator's connection to the printed circuit board is in some examples enhanced through use of a thermal paste to ensure good thermal conductivity between the vertically integrated voltage regulator and the printed circuit board. In some embodiments, the printed circuit board may have a heat sink 426 mounted to it, or may comprise one or more thermal pipes 428 or other structures that are thermally more conductive than printed circuit board 420 to conduct heat away from the vertically integrated voltage regulator 408 to the heat sink 426.

The examples of FIGS. 3 and 4 again provide for configuration of at least a portion of the vertically integrated voltage regulator assembly and at least a portion of the integrated circuit die to be intersected by an axis normal to and through the mounting surfaces of the integrated circuit die and the vertically integrated voltage regulator assembly. This configuration further places the vertical integrated voltage regulator physically close to the integrated circuit die, such that physical distance and electrical impedance between the vertically integrated voltage regulator and the integrated circuit die are low.

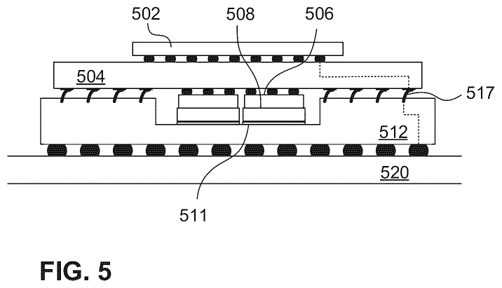

FIG. 5 is a side view of an integrated circuit package and a vertically integrated voltage regulator mounted on opposite sides of a printed circuit board, consistent with an example embodiment. Here, an integrated circuit die 502 is mounted to a substrate 504 such as via an underfilled flip chip ball grid array, similar to other examples presented herein. The substrate may be mounted to a socket 512 using a Ball Grid Array (BGA), Land Grid Array (LGA), copper pillars coated in solder, or similar technology to electrically coupling the integrated circuit die 502 to circuit traces comprising a part of the printed circuit board 520 (which is in this example coupled to the socket using solder bumps).

A vertically integrated voltage assembly comprising inductors 506 and vertically integrated voltage circuits 508 may be mounted to the substrate 504 using bumps such as fine pitch solder bumps and/or the like, and may receive a high voltage power signal and provide low voltage regulated power to the integrated circuit 502 via these connections. The vertically integrated voltage regulator assembly in this example may further comprise a thermal interface 511, such as thermal paste, thermally conductive metal, and/or another such material to facilitate heat transfer from the voltage regulator assembly to socket 512.

The vertically integrated voltage regulator assembly comprising inductors 506, vertically integrated voltage circuits 508, and thermal interface 511 may comprise one of two or more such assemblies in some examples, as shown here. In examples where more than one vertically integrated voltage regulator may be present per integrated circuit die, various voltage regulator assemblies may provide different voltage levels for different processor cores on a die, or a vertically integrated voltage regulator may provide power to more than one integrated circuit die. This may be achieved in some examples by using a defined pattern for vertically integrated voltage regulators, such as having a standardized size, physical and/or electrical connection configuration, and/or other such characteristics to facilitate easy integration of a desired number, type, or other variation of vertically integrated voltage regulator assembly configuration into a specific embodiment.

In one such example, a voltage regulator assembly may power eight individual processor cores on integrated circuit 502, such as where a 64-core processor with 16 high performance cores and 48 efficient cores comprises two higher power voltage regulator assemblies for the 16 high performance cores and six lower power voltage regulator assemblies for the 48 efficient cores. In other examples, a voltage regulator assembly may power a single processor core or another number of cores. Such patterns may be repeated multiple times on a single integrated circuit, substrate, or voltage regulator interface, such as a ball grid array, or may be in a standard configuration repeated across different applications such that standardized vertically integrated voltage regulator assemblies may be selected and coupled to integrated circuit die and substrate assemblies.

Some computerized devices may support more than one mounted integrated circuit having various voltage regulator assemblies, such as a printed circuit board serving as a motherboard for a server that may contain many separate integrated circuit dies that each have one or more associated vertically integrated voltage regulators. In one such example, a printed circuit board motherboard may have tens of integrated circuits dies and associated substrates attached, each having one or more vertically integrated voltage regulators providing power for the various processor cores on each integrated circuit die through a standardized or repeatable interface such as a pattern of flip chip ball grid array balls.

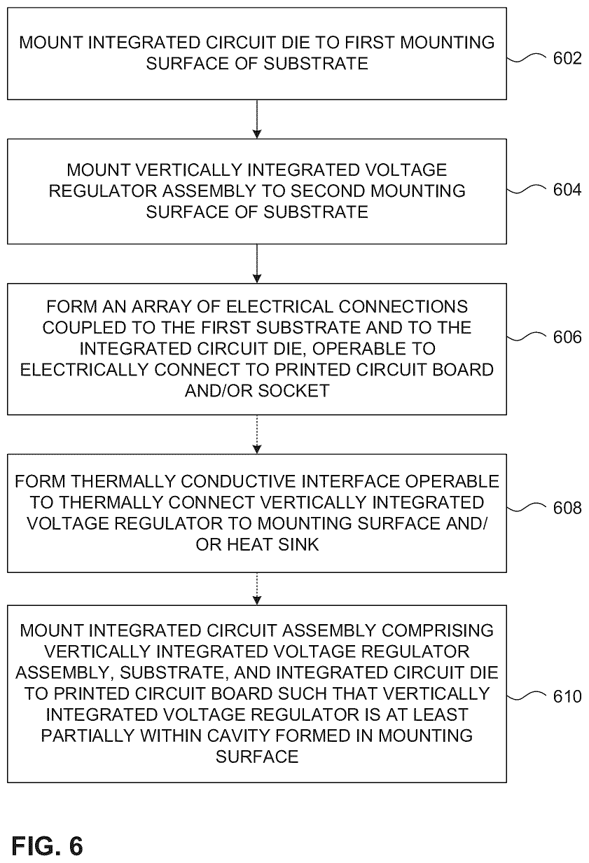

FIG. 6 is a flow diagram of a method of assembling an integrated circuit package with a vertically integrated voltage regulator assembly, consistent with an example embodiment. At 602, an integrated circuit die is mounted to a substrate, such as using a flip-chip ball grid array or other suitable method. An underfill may be applied, such as via capillary action, to fill any air space between the integrated circuit die and the substrate. A vertically integrated voltage regulator assembly is mounted to the substrate at 604, such as on a mounting surface opposite the mounting surface to which the integrated circuit die is mounted. Similar methods such as flip chip ball grid array mounting and underfilling or other such methods may be employed. In a more detailed example, the substrate is mounted to the integrated circuit die and the vertically integrated voltage regulator assembly such that at least a portion of the vertically integrated voltage regulator assembly and at least a portion of the integrated circuit die are intersected by an axis normal to and through their respective mounting surfaces.

An array of electrical connections are formed on the substrate at 606, operable to electronically connect the substrate to a printed circuit board and/or a socket, and to connect circuits on the printed circuit board to the integrated circuit die via conductive elements in the substrate. The substrate may further conduct electrical power signals to the vertically integrated voltage regulator, enabling the voltage regulator to receive relatively high current power signals, and to provide regulated supply voltage power signals to the integrated circuit die and monitor voltages on the integrated circuit die with relatively low latency and impedance.

At 608, a thermally conductive interface is optionally formed on a surface of the vertically integrated voltage regulator, and is operable to conduct thermal heat away from the vertically integrated voltage regulator toward a heat sink, environmental air, liquid cooling, or the like. In further examples, a fan, pump, or other such means may be employed to move gas or liquid across the heat sink, facilitating transfer of heat away from the heat sink.

The integrated circuit assembly with the vertically integrated voltage regulator may be mounted, such as by a manufacturer, end user, or another party to a printed circuit board for use in a computerized system or other electronic device at 610 by mounting the integrated circuit assembly comprising the vertically integrated voltage regulator assembly, the substrate, and the integrated circuit die to a printed circuit board, a socket on a printed circuit board, or the like such that the vertically integrated voltage regulator is at least partially within a cavity formed in the mounting surface. The cavity may be formed in a mounting surface, such as a printed circuit board, specifically to receive the vertically integrated voltage regulator assembly, or may be a manufactured part of the mounting surface such as where a socket is cast or otherwise formed with a cavity therein operable to receive at least a portion of the vertically integrated voltage regulator.

The examples presented herein illustrate how a vertically integrated voltage regulator may be positioned physically near an integrated circuit die such that signal travel distance and signal impedance between the vertically integrated voltage regulator and the integrated circuit die are low. A cavity may be used in a mounting surface for the integrated circuit assembly in some examples to receive at least a part of the vertically integrated voltage regulator assembly, which in some examples is desirable to create sufficient space between the substrate and the mounting surface for the vertically integrated voltage regulator to reside. A heat sink or thermal interface from the vertically integrated voltage regulator may further be provided in some examples, providing a thermal connection between the vertically integrated voltage regulator and the mounting surface (such as a socket, printed circuit board, heat sink portion, or the like), enabling the mounting surface to carry heat away from the vertically integrated voltage regulator and to be dispersed.

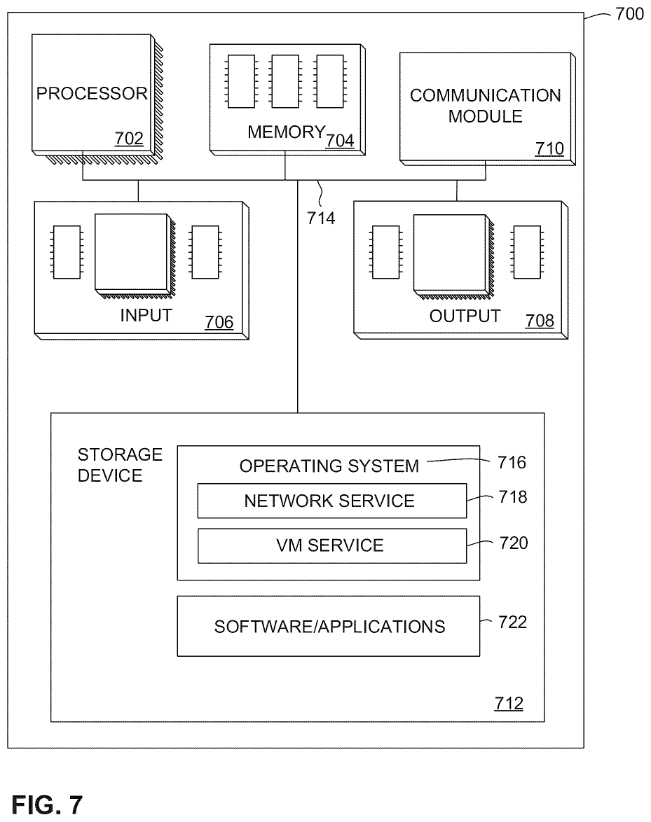

FIG. 7 shows a block diagram of a general-purpose computerized system, consistent with an example embodiment. FIG. 7 illustrates only one particular example of computing device 700, and other computing devices 700 may be used in other embodiments. Although computing device 700 is shown as a standalone computing device, computing device 700 may be any component or system that includes one or more processors or another suitable computing environment for executing software instructions in other examples, and need not include all of the elements shown here.

As shown in the specific example of FIG. 7, computing device 700 includes one or more processors 702, memory 704, one or more input devices 706, one or more output devices 708, one or more communication modules 710, and one or more storage devices 712. Computing device 700, in one example, further includes an operating system 716 executable by computing device 700. The operating system includes in various examples services such as a network service 718 and a virtual machine service 720 such as a virtual server. One or more applications, such as application 722 are also stored on storage device 712, and are executable by computing device 700.

Each of components 702, 704, 706, 708, 710, and 712 may be interconnected (physically, communicatively, and/or operatively) for inter-component communications, such as via one or more communications channels 714. In some examples, communication channels 714 include a system bus, network connection, inter-processor communication network, or any other channel for communicating data. Applications such as software application 722 and operating system 716 may also communicate information with one another as well as with other components in computing device 700.

Processors 702, in one example, are configured to implement functionality and/or process instructions for execution within computing device 700. For example, processors 702 may be capable of processing instructions stored in storage device 712 or memory 704. Examples of processors 702 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 712 may be configured to store information within computing device 700 during operation. Storage device 712, in some examples, is known as a computer-readable storage medium. In some examples, storage device 712 comprises temporary memory, meaning that a primary purpose of storage device 712 is not long-term storage. Storage device 712 in some examples is a volatile memory, meaning that storage device 712 does not maintain stored contents when computing device 700 is turned off. In other examples, data is loaded from storage device 712 into memory 704 during operation. Examples of volatile memories include random access memories (RAM), dynamic random access memories (DRAM), static random access memories (SRAM), and other forms of volatile memories known in the art. In some examples, storage device 712 is used to store program instructions for execution by processors 702. Storage device 712 and memory 704, in various examples, are used by software or applications running on computing device 700 such as software application 722 to temporarily store information during program execution.

Storage device 712, in some examples, includes one or more computer-readable storage media that may be configured to store larger amounts of information than volatile memory. Storage device 712 may further be configured for long-term storage of information. In some examples, storage devices 712 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 700, in some examples, also includes one or more communication modules 710. Computing device 700 in one example uses communication module 710 to communicate with external devices via one or more networks, such as one or more wireless networks. Communication module 710 may be a network interface card, such as an Ethernet card, an optical transceiver, a radio frequency transceiver, or any other type of device that can send and/or receive information. Other examples of such network interfaces include Bluetooth, 4G, LTE, or 5G, WiFi radios, and Near-Field Communications (NFC), and Universal Serial Bus (USB). In some examples, computing device 700 uses communication module 710 to wirelessly communicate with an external device such as via a public network.

Computing device 700 also includes in one example one or more input devices 706. Input device 706, in some examples, is configured to receive input from a user through tactile, audio, or video input. Examples of input device 706 include a touchscreen display, a mouse, a keyboard, a voice responsive system, video camera, microphone or any other type of device for detecting input from a user.

One or more output devices 708 may also be included in computing device 700. Output device 708, in some examples, is configured to provide output to a user using tactile, audio, or video stimuli. Output device 708, in one example, includes a display, a sound card, a video graphics adapter card, or any other type of device for converting a signal into an appropriate form understandable to humans or machines. Additional examples of output device 708 include a speaker, a light-emitting diode (LED) display, a liquid crystal display (LCD or OLED), or any other type of device that can generate output to a user.

Computing device 700 may include operating system 716. Operating system 716, in some examples, controls the operation of components of computing device 700, and provides an interface from various applications such as software application 722 to components of computing device 700. For example, operating system 716, in one example, facilitates the communication of various applications such as software application 722 with processors 702, communication unit 710, storage device 712, input device 706, and output device 708. Applications such as application 722 may include program instructions and/or data that are executable by computing device 700. These and other program instructions or modules may include instructions that cause computing device 700 to perform one or more of the other operations and actions described in the examples presented herein.

Process cores, bitcell arrays, memory structures, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, System Verilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and System Verilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112(f) so that it is specifically intended that 35 USC § 112(f) not be implicated by use of the term “computing device,” “processor,” “processing unit,” “processing circuit” and/or similar terms; however, if it is determined, for some reason not immediately apparent, that the foregoing understanding cannot stand and that 35 USC § 112(f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some embodiments may be described, at least in part, by the following numbered clauses or by any combination thereof:

Clause 1: An assembly, comprising: an integrated circuit die; a substrate electrically and physically coupled to the integrated circuit die on a first mounting surface of the substrate; a vertically integrated voltage regulator assembly comprising one or more inductors and one or more voltage regulation circuits, the vertically integrated voltage regulator assembly electrically and physically connected to the substrate at a physical location on a second mounting surface of the substrate opposite the first mounting surface of the substrate, wherein at least a portion of the vertically integrated voltage regulator assembly and at least a portion of the integrated circuit die are intersected by an axis normal to and through first and second mounting surfaces; and an array of electrical connections coupled to the substrate and electrically connected to the integrated circuit die, the array of electrical connections operable to electrically connect the substrate to a printed circuit board and/or to a socket.

Clause 2: The assembly of clause 1, further comprising a thermally conductive interface between the vertically integrated voltage regulator assembly and a socket.

Clause 3: The assembly of clause 2 or any of the aforementioned clauses, further comprising at least one additional integrated circuit die electrically coupled to the substrate and/or an interposer electrically and physically coupling the integrated circuit die and the at least one additional integrated circuit die to the substrate.

Clause 4: The assembly of any of the aforementioned clauses, wherein the vertically integrated voltage regulator assembly electrical connection to the package substrate comprises at least one power supply signal, at least one power delivery signal, and at least one voltage monitoring signal.

Clause 5: The assembly of any of the aforementioned clauses, wherein the array of electrical connections coupled to the substrate comprise a land grid array (LGA), a pin grid array (PGA), or a Ball Grid Array (BGA).

Clause 6: The assembly of any of the aforementioned clauses, further comprising a socket electrically and physically coupled to a motherboard, the socket operable to electrically connect to the substrate via the array of electrical connections.

Clause 7: The assembly of clause 6 or any of the aforementioned clauses, further comprising a cavity formed in the socket, the vertically integrated voltage regulator assembly physically located at least partially within the cavity formed in the socket.

Clause 8: The assembly of any of the aforementioned clauses, further comprising a printed circuit board, the array of electrical connections electrically connected to the printed circuit board, and further comprising a cavity formed in the printed circuit board, the vertically integrated voltage regulator assembly physically located at least partially within the cavity formed in the printed circuit board.

Clause 9: The assembly of any of the aforementioned clauses, further comprising a plurality of vertically integrated voltage regulator assemblies, each of the vertically integrated voltage regulator assemblies having a physical configuration, electrical configuration, or a combination thereof that are repeated between such assemblies to facilitate integration of various such vertically integrated voltage regulator assemblies.

Clause 10: The assembly of clause 9, wherein the integrated circuit die comprises plurality of processing cores, and the plurality of vertically integrated voltage regulator assemblies are configured to provide power to the plurality of processing cores.

Clause 11: A method of forming an integrated circuit assembly, comprising: physically and electrically coupling an integrated circuit die to a first mounting surface of a substrate; physically and electrically coupling a vertically integrated voltage regulator assembly to the substrate at a physical location on a second mounting surface of the substrate opposite the first mounting surface of the substrate, wherein at least a portion of the vertically integrated voltage regulator assembly and at least a portion of the integrated circuit die are intersected by an axis normal to and through the first and second mounting surfaces, the vertically integrated voltage regulator assembly comprising one or more inductors and one or more voltage regulation circuits; and forming an array of electrical connections coupled to the substrate and electrically connected to the integrated circuit die, the array of electrical connections further operable to electrically connect the substrate to a printed circuit board and/or to a socket.

Clause 12: The method of forming an integrated circuit assembly of clause 11, further comprising forming a thermally conductive interface between the vertically integrated voltage regulator assembly and a socket.

Clause 13: The method of forming an integrated circuit assembly of any of clauses 11-12, forming the thermally conductive interface further comprising applying thermal paste.

Clause 14: The method of forming an integrated circuit assembly of any of clauses 11-13, wherein the vertically integrated voltage regulator assembly electrical connection to the package substrate comprises at least one power supply signal, at least one power delivery signal, and at least one voltage monitoring signal.

Clause 15: The method of forming an integrated circuit assembly of any of clauses 11-14, wherein the array of electrical connections coupled to the substrate comprise a land grid array (LGA), a pin grid array (PGA), or a Ball Grid Array (BGA).

Clause 16: The method of forming an integrated circuit assembly of any of clauses 11-15, further comprising a socket electrically and physically coupled to a motherboard, the socket operable to electrically connect to the substrate via the array of electrical connections.

Clause 17: The method of forming an integrated circuit assembly of any of clauses 11-16, further comprising forming a cavity formed in the socket, the vertically integrated voltage regulator assembly physically located at least partially within the cavity formed in the socket.

Clause 18: The method of forming an integrated circuit assembly of any of clauses 11-17, further comprising electrically connecting the array of electrical connections to a printed circuit board.

Clause 19: The method of forming an integrated circuit assembly of any of clauses 11-18, further comprising a forming a cavity in the printed circuit board, the vertically integrated voltage regulator assembly physically located at least partially within the cavity formed in the printed circuit board.

Clause 20: An assembly, comprising: an integrated circuit die; a substrate electrically and physically coupled to the integrated circuit die on a first mounting surface of the substrate; a printed circuit board electrically and physically coupled to the substrate at a physical location on a second mounting surface of the substrate opposite the first mounting surface of the substrate, and on a first mounting surface of the printed circuit board; and a vertically integrated voltage regulator assembly comprising one or more inductors and one or more voltage regulation circuits, the vertically integrated voltage regulator assembly electrically and physically connected to the printed circuit board at a physical location on a second mounting surface of the printed circuit board opposite the first mounting surface of the printed circuit board, wherein at least a portion of the vertically integrated voltage regulator assembly and at least a portion of the integrated circuit die are intersected by an axis normal to and through the first and second mounting surfaces of the printed circuit board.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. An assembly, comprising:
an integrated circuit die;
a substrate electrically and physically coupled to the integrated circuit die on a first mounting surface of the substrate;
a vertically integrated voltage regulator assembly comprising one or more inductors and one or more voltage regulation circuits, the vertically integrated voltage regulator assembly electrically coupled to the substrate at a physical location on a second mounting surface of the substrate opposite the first mounting surface of the substrate, wherein at least a portion of the vertically integrated voltage regulator assembly and at least a portion of the integrated circuit die are intersected by an axis normal to and through first and second mounting surfaces; and
an array of electrical connections electrically and physically coupled to the second mounting surface of the substrate and electrically coupled to the integrated circuit die, the array of electrical connections operable to electrically connect the substrate to a printed circuit board and/or to a socket.

2. The assembly of claim 1, further comprising a thermally conductive interface between the vertically integrated voltage regulator assembly and the socket.

3. The assembly of claim 1, further comprising at least one additional integrated circuit die electrically coupled to the substrate and/or an interposer electrically and physically coupling the integrated circuit die and the at least one additional integrated circuit die to the substrate.

4. The assembly of claim 1, wherein the vertically integrated voltage regulator assembly electrical coupling to the substrate comprises at least one power source supply signal, at least one power delivery signal, and at least one voltage monitoring signal.

5. The assembly of claim 1, wherein the array of electrical connections coupled to the substrate comprise a land grid array (LGA), a pin grid array (PGA), or a Ball Grid Array (BGA).

6. The assembly of claim 1, further comprising a socket operable to electrically connect to the substrate via the array of electrical connections.

7. The assembly of claim 6, further comprising a socket cavity formed in the socket, the vertically integrated voltage regulator assembly physically located at least partially within the socket cavity formed in the socket.

8. The assembly of claim 1, and further comprising:
a printed circuit board (PCB), the array of electrical connections electrically coupled to the PCB;
and a printed circuit board cavity formed in the PCB, wherein the vertically integrated voltage regulator assembly to be physically located at least partially within the printed circuit board cavity formed in the PCB.

9. The assembly of claim 1, further comprising a plurality of vertically integrated voltage regulator assemblies, each of the vertically integrated voltage regulator assemblies having a physical configuration, electrical configuration, or a combination thereof that are repeated between such assemblies to facilitate integration of various such vertically integrated voltage regulator assemblies.

10. The assembly of claim 9, wherein the integrated circuit die comprises plurality of processing cores, and the plurality of vertically integrated voltage regulator assemblies to be configured to provide power to the plurality of processing cores.

11. A method of forming an integrated circuit assembly, comprising:
physically and electrically coupling an integrated circuit die to a first mounting surface of a substrate;
physically and electrically coupling a vertically integrated voltage regulator assembly to the substrate at a physical location on a second mounting surface of the substrate opposite the first mounting surface of the substrate, wherein at least a portion of the vertically integrated voltage regulator assembly and at least a portion of the integrated circuit die are intersected by an axis normal to and through the first and second mounting surfaces, the vertically integrated voltage regulator assembly comprising one or more inductors and one or more voltage regulation circuits; and
forming an array of electrical connections coupled to the substrate and electrically connected to the integrated circuit die, the array of electrical connections further operable to electrically connect the substrate to a printed circuit board and/or to a socket.

12. The method of forming an integrated circuit assembly of claim 11, further comprising forming a thermally conductive interface between the vertically integrated voltage regulator assembly and a socket.

13. The method of forming an integrated circuit assembly of claim 12, forming the thermally conductive interface further comprising applying thermal paste.

14. The method of forming an integrated circuit assembly of claim 11, wherein the vertically integrated voltage regulator assembly electrical connection to the package substrate comprises at least one power supply signal, at least one power delivery signal, and at least one voltage monitoring signal.

15. The method of forming an integrated circuit assembly of claim 11, wherein the array of electrical connections coupled to the substrate comprise a land grid array (LGA), a pin grid array (PGA), or a Ball Grid Array (BGA).

16. The method of forming an integrated circuit assembly of claim 11, further comprising a socket electrically and physically coupled to a motherboard, the socket operable to electrically connect to the substrate via the array of electrical connections.

17. The method of forming an integrated circuit assembly of claim 16, further comprising forming a cavity formed in the socket, wherein the vertically integrated voltage regulator assembly to be physically located at least partially within the cavity formed in the socket.

18. The method of forming an integrated circuit assembly of claim 11, further comprising electrically connecting the array of electrical connections to a printed circuit board.

19. The method of forming an integrated circuit assembly of claim 18, further comprising a forming a cavity in the printed circuit board, wherein the vertically integrated voltage regulator assembly physically to be located at least partially within the cavity formed in the printed circuit board.

20. An assembly, comprising:
an integrated circuit die;
a substrate electrically and physically coupled to the integrated circuit die on a first mounting surface of the substrate;
a printed circuit board comprising a first mounting surface and a second mounting surface, the first mounting surface of the printed circuit board electrically and physically coupled to the substrate at a physical location on a second mounting surface of the substrate opposite the first mounting surface of the substrate; and
a vertically integrated voltage regulator assembly comprising one or more inductors and one or more voltage regulation circuits, the vertically integrated voltage regulator assembly electrically and physically connected to the printed circuit board at a physical location on the second mounting surface of the printed circuit board opposite the first mounting surface of the printed circuit board, wherein at least a portion of the vertically integrated voltage regulator assembly and at least a portion of the integrated circuit die are intersected by an axis normal to and through the first and second mounting surfaces of the printed circuit board.
